(19) United States
(12) Patent Application Publication
(10) Pub. No.: US 2006/0240335 A1
(43) Pub. Date: Oct. 26, 2006

(54) Mask blank and process for producing and process for using the same, and mask and process for producing and process for using the same

(76) Inventor: Soichiro Mitsui, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/387,954

(22) Filed: Mar. 24, 2006

(30) Foreign Application Priority Data
Mar. 24, 2005 (JP) P 2005-085976

(51) Int. Cl. B32B 9/00; B32B 17/10; B32B 17/06; G03F 1/00

(52) U.S. Cl. 430/5; 428/428; 428/430

(57) ABSTRACT

By applying a transparent electroconductive film to a mask blank or by forming an electroconductive layer by doping metallic ions thereto, such a mask blank can be provided that an electrostatic chuck having a sufficient retaining force can be applied, the front and back surfaces of the mask blank can be measured simultaneously with ultimate accuracy, generation of dusts is extremely reduced, and charge prevention and prevention of particle adhesion are enabled, and a process for producing the mask blank, a process for using the mask blank, a mask using the mask blank, a process for producing the mask, and a process for using the mask can be also provided.

### CROSS-REFERENCE TO RELATED APPLICATIONS

This application is based on and claims the benefit of priority from the prior Japanese Patent Application No. 2005-085976, filed on Mar. 24, 2005; the entire contents of which are incorporated herein by reference.

### BACKGROUND OF THE INVENTION

1. Field of the Invention

The present invention relates to a mask blank used in a mask for a circuit original plate used in a lithography process for producing a semiconductor device, and in particular, it relates to a structure of a mask blank, and a process for producing and process for using a mask blank.

2. Description of the Related Art

In recent years, EUVL (extreme ultra violet lithography), which is a reducing reflection projection exposure technique using a soft X-ray having a wavelength of from 5 to 15 nm, is receiving attention as a next-generation lithography technique, and is being developed worldwide. In the lithography technique, a mask, an illumination optical system and a projection optical system are all constituted in the form of a reflection type because there is no substance (material) suitable for a refracting optical device in the EUV region. The mask has a Mo/Si multilayer film exhibiting high reflectance to EUV light formed therein, and the light shielding member uses an absorbent to EUV light, such as Cr and Ta systems.

An EUV exposure apparatus is planed to employ a system that is similar to the so-called photo-exposure tool (or, scanning exposure tool), in which a mask is irradiated with illumination light in a ring form in an oblique direction at an incident angle of about 6° with scanning the mask and a substrate to be exposed (wafer) relative to the projection optical system at a velocity ratio corresponding to the reduction ratio, whereby the reflected light from the mask surface is reduced and projected to form a mask pattern on the wafer. In the reflection exposure system, a non-telecentric projection optical system is used on the side of the mask, and therefore, there arises a problem of image shift, in which the image location is deviated within the plane due to irregularity on the mask surface. For example, in the case where the height of the mask, on which a certain pattern is formed, is deviated from the reference level by 1 μm, the projected image location of the pattern is deviated on the wafer from the original position by about 26 nm.

Furthermore, as similar to the ordinary photomasks, there is a problem of deviation in location due to elastic deformation of the mask, and deviation in location of a pattern occurs due to the weight of the mask, the stress from various thin films (such as a multilayer film, an absorbent and a buffer), the temperature and the retention. Among these, the stress from various thin films causes a problem of deviation in pattern location due to irregularity in stress within the plane because an EUV mask has a complex film structure. In order to suppress the deviation in location due to the projection optical system and the deformation of the substrate, it is required to maintain the flatness of the mask to such high accuracy as about 50 nm or less.

In order to attain the requirement, there has been proposed that the outer shape of the mask and the outer shape of a chuck for retaining the mask are standardized to form an ideal plane, and these are forcedly chucked to form a mask surface with an ideal flat surface in a state where the mask is retained. In this method, the flatness required in the EUVL mask for the 45-nm generation on the front and back surfaces is 50 nm (p-v) or less for irregularity having a spatial frequency of 150 mm and 3 nm (p-v) or less for irregularity having a special frequency of 10 mm. The flatness required in the chuck is 50 nm (p-v) or less for a special frequency of 150 mm and 3 nm (p-v) or less for a special frequency of 10 mm. In the solution by shape standardization, a mask having sufficiently small irregularity can be realized ideally by installing a mask by using a mask and a chuck having been standardized in flatness, and therefore, the deviation in location due to change in shape of the substrate can be avoided. The aforementioned required values in irregularity are defined for reducing the deviation in location in a plane within 1 nm. Furthermore, in order to chuck the mask forcedly to form a mask surface with an ideal flat surface in a state where the mask is retained, it is considered that the chucking force is necessarily at least 15 kPa. The basis of the value of 15 kPa is such a value that is required to withstand the acceleration of the stage upon scanning exposure of the mask on the exposing apparatus. That is, the value can be understood as the minimum retaining force for preventing dropout or deviation of the mask from occurring upon scanning exposure.

However, there are various problems on realizing the ideal flatness by the aforementioned method. For example, a mask may not be sufficiently reformed with a chucking force of 15 kPa depending on the flat shape (warpage) of the completed mask.

In the case where a particle is bitten between the contact surfaces of the mask and the chuck, the intended flat surface of the mask cannot be formed. In general, a particle is prevented is prevented probabilistically from being bitten by reducing the contact area of the chuck surface by several percents, but it is significantly difficult to control completely a particle on the back surface of the mask, and furthermore, the mask may not be retained with the sufficient chucking force by reducing the contact area. In this case, not only the warping deformation of the mask cannot be reformed, but also it is difficult to retain the mask.

Furthermore, as described hereinabove, in an EUVL exposure apparatus, it is necessary that the exposing atmosphere in the vicinity of the mask, the reflection optical system and the substrate to be exposed is in an ultrahigh vacuum state. In this case, a vacuum chuck, which is used in the ordinary optical exposure apparatus, cannot be used. Accordingly, a so-called electrostatic chuck is employed as a mask chuck of an EUVL exposure apparatus.

Fused silica glass is generally used as a mother material of a mask, and it is proposed that a glass material is similarly used as a mask for EUVL. However, taking thermal deformation due to increase in temperature upon exposure into consideration, there is such a problem that ordinary silica glass cannot satisfy the required location accuracy on thermal deformation. Accordingly, it is studied that such glass materials as ULE (registered trade name) or Zerodur (registered trade name) having a lower expansion coefficient than silica glass are used as a mother material of a mask for EUVL.

However, the retaining force of an electrostatic chuck to a glass material is smaller than that to an Si wafer, and thus it is necessary to increase the application voltage about 10 times the case of an Si wafer. For example, a retaining force of about 15 kPa can be obtained with an application voltage of from 2 to 3 kV. Although a larger chucking force is obtained by increasing the application voltage, it is not easily practiced since it may be associated with problems in withstand voltage of dielectric breakdown and increase in leakage current. Therefore, the chucking force itself has an upper limit. As having been described, firstly, there is demanded to provide such an electrostatic chucking system that can retain a glass substrate with a sufficient retaining force.

For example, JP-A-2002-299228 discloses that an electroconductive metallic film is formed on a chucking surface (back surface) of a mask for retaining a glass substrate, and Cr, Ni, Ta, and other metals, alloys and semiconductors can be used. This realizes a sufficient chucking force through the electroconductive film.

However, the species of metallic films disclosed therein are opaque to laser light that is generally used in a mask flatness measuring apparatus, and therefore, there is such a risk that a problem occurs in a step of inspecting a mask in the production process of a mask blank described below. In particular, such a problem may occur that sufficient inspection cannot be carried out due to shortage in measurement accuracy, so as to reduce the yield of non-defective products.

In the production process of a mask blank, a glass substrate having no film formed is subjected to working, polishing, finalizing and rinsing, and then subjected to inspection for appearance, worked dimensions, flatness, thickness and parallelism, and inspection of defects and particles. In this stage, an optical means is used for measuring parallelism, thickness and the like, and for example, the front surface (or the back surface) of the mask blank is irradiated in one direction with inspection light at a substantially perpendicular (or oblique) angle to measure based on the principle of flatness interferometer. Subsequently, various thin films are formed thereon, and upon formation of the each film, inspection and rinsing are carried out. In the production process of a mask blank having a light shielding film or an absorbent film, the shape of the substrate, the working accuracy, the flatness and the thickness are also inspected by an optical means.

In the case where an electroconductive film that is opaque to the inspection light is formed on the back surface as in an EUVL mask, the substrate must reset for measuring the thickness, the parallelism and the flatness of the front and back surfaces of the substrate. Upon resetting the substrate, the random error is increased in √2 times because of the measurement errors due to influence of difference in retaining the substrate before and after resetting and the random errors of the measurements in twice. In this case, there is such a risk that the measurement accuracy cannot satisfy the substrate inspection specification. It is the specification of an EUV mask that the flatness within a region of 10 mm is less than 3 nm (p-v), and therefore, it is demanded to avoid measurement error as much as possible. Therefore, it is desired to avoid such an operation that the front surface and the back surface of the mask are separately measured for flatness, which includes resetting of the mask, and deformation during measurement due to slight warpage upon retaining the mask and the thermal deformation of the mask.

As similar to the production of an ordinary photomask, it is a significant problem that adhesion of particles during the production process largely influences the yield. A mask having a resist coated thereon is irradiated with an electron beam in the electron beam drawing step, a problem of adhesion of particles occurs due to charging when the prevention of charging up is insufficient.

There are some cases where a photomask has no Cr film on a mask peripheral part, particularly on an edge part. A resist is coated thereon, and the resist in the peripheral part is removed by edge cut in some cases. In the mask having such a structure, glass as an insulating material is exposed at the peripheral part or the edge part. Upon irradiating the glass part with an electron beam upon drawing, charge up occurs to change the surface potential, which deviates the orbital of the electron beam. It brings about such a problem that the beam does not hit on the prescribed location to deteriorate the positional accuracy. In order to avoid the problem, there are some cases where a charge preventing film (polymer electroconductive film) is coated after coating the resist. In the case where charge up occurs excessively, the glass and the resist in those parts are scattered due to discharge to form particles. Moreover, discharge breakdown may further occur to cause damage and deterioration of the mask material and the Cr film. The charge up phenomenon occurs not only in the electron beam drawing step, but also in a mask production step due to ion irradiation for dry etching, which brings about such a problem that sufficient working accuracy cannot be obtained due to deterioration in etching uniformity and increase in micro loading effect. The same problem occurs in the pattern inspection using an electron beam and repair of defects by FIB (focused ion beam). In the production steps subsequent to the drawing step, the charge preventing film may be insufficient to avoid the problems.

Under the circumstances, a proposal has been made to solve the problem associated with charging, for example, in Japanese Patent No. 2,500,526. JP-A-2-211450 discloses formation of a transparent electroconductive film for preventing charge up upon phase shift drawing after forming a Cr pattern. Upon conveying a mask in various kinds of process apparatuses, there arises a problem of attracting particles by a charge part, in the case where charge is not sufficiently prevented from occurring. During the process steps and in a rinsing step of the completed mask, there is also such a problem that particles are adhered to the mask, which functions as a dust collector, in the case where charge is not sufficiently prevented from occurring. JP-A-4-39660 discloses a substrate for a photomask having a transparent electroconductive film (molybdenum silicide oxinitride) provided between a silica glass substrate and a chromium film. In this technique, charge prevention is effected by using a molybdenum silicide oxinitride having a transmittance of 75% or more to an exposure wavelength of 436 nm for preventing the exposure characteristics from being deteriorated. However, the molybdenum silicide oxinitride is provided between the silica glass substrate and the chromium film as a light shielding film, i.e., only on the front surface side of the substrate, and therefore, it cannot impart electroconductivity to the back surface to enable electrostatic chucking. Furthermore, in order to apply the technique of Patent Document 5 to a mask for the 45-nm generation in the future, it is necessary that the molybdenum silicide oxinitride has a transmittance close to 100% as much as possible to excimer exposure light having a wavelength of about 193 nm, but there is such a risk that the requirement cannot be satisfied.

In the case where a completed mask is used by installing in an exposure apparatus, charge prevention and earthing are important for preventing particles from being adhered. Particularly, in the case where a mask is irradiated with a high-energy ray, there are other phenomena since influence of the photoelectric effect is necessarily considered. For example, EUV light having a wavelength of 13.5 nm has energy of about 92 eV, which is sufficiently larger than the work function of a metallic film (in eV order), and thus photoelectrons are emitted from a metallic film, such as a light shielding film and a multilayer film, by the photoelectric effect. Accordingly, in the case where the mask is in a state where earthing is insufficient, the surface of the mask is positively charged due to disruption of the charge balance in the metallic film, which brings about such a risk that the mask functions as a dust collector.

Apart from the viewpoint of particles, on the other hand, it is necessary that a mask has a uniform surface potential for realizing high positional accuracy of patterns in a pattern drawing apparatus using an electron beam. In the case where glass as an insulating material is exposed at the peripheral part or the edge part of the mask, a uniform surface potential cannot be obtained to deteriorate the positional accuracy of patterns. It is necessary therefore that reliable earthing is ensured for charge prevention. The problem occurs similarly in a process apparatus and an exposure apparatus. However, since a mother material of a mask is silica glass as an insulating material, earthing failure occurs when the apparatus has an insufficient earthing mechanism.

Upon conveying and retaining a mask and upon taking out and putting in a mask to a mask carrier, dusts are generated in the case where the mask is in physical contact thereto, particularly the mask is scratched thereby. For example, upon electrostatically chucking the aforementioned EUV mask, dusts are generated due to wear of the contact part of the mask and wear of the chuck upon putting on and taking off. The problem occurs similarly upon handing by a conveying robot. Because the problem brings about a fatal error, such as release of a film and significant generation of dusts, it is necessary that the characteristics, such as the adhesion property and the brittleness, of the electroconductive film on the back surface of the mask are carefully considered. There is another problem that the substrate is deformed due to the internal stress of the electroconductive film itself and the thermal stress thereof upon forming the film, the film forming process and the conditions therefor are important issues as similar to the selection of film species. It is necessary as having been described that a back surface of an EUVL mask has a flatness in the order to 50 nm from the standpoint of requirement in positional accuracy of patterns. Therefore, the deformation of the substrate upon film formation is necessarily less than 50 nm, and the permissible particle size is also less than 50 nm.

Taking the prevention of pattern defects and the exposure characteristics into consideration, it is necessary that particles having a smaller size are prevented from being generated on the front surface of the mask having patterns formed thereon.

The aforementioned problems are summarized below.

(1) Problem of shortage in chucking force with glass mother material

The retaining force with an electrostatic chuck is insufficient. The positional accuracy of patterns is deteriorated by shortage in force for reforming warpage.

(2) Problem of electroconductive film (metallic film) on back surface

The accuracy on inspecting a mask blank is insufficient. Dust are generated upon conveying a mask and scratching on putting on and taking off a mask. A mask is deformed due to formation of an electroconductive film on the back surface.

(3) Problem of charging

A glass mother material as an insulating material suffers charging, attraction particles, discharge breakdown and non-uniform surface potential, so as to deteriorate positional accuracy of drawn patterns. Problems occur in the process, such as etching, SEM inspection and FIB repair. The photoelectric effect occurs upon exposure.

In the case where a mask blank or a mask having insulating glass as a mother material is retained in vacuum, they are difficult to chuck electrostatically to cause a problem of shortage in chucking force. In the case where an opaque electroconductive film of a metallic film is formed on a back surface, a mask blank cannot be inspected in shape with ultimate accuracy, and there is also a problem in generation of dusts due to scratching the electroconductive film upon handling and detaching the mask blanks or the mask. Furthermore, there is also a problem in charging due to the photoelectric effect upon charging and exposing a mask blank or a mask having insulating glass as a mother material, which is exposed in the peripheral part of the mask.

### SUMMARY OF THE INVENTION

The invention has been developed taking the aforementioned problems into consideration, and an object thereof is to provide such a mask blank and a mask that can be applied with an electrostatic chuck, suffer no generation of dusts, and can be prevented from charging and adhesion of particles. Another object of the invention is to provide a process for producing of such a mask blank and a process for using a mask blank that enable inspection of the shape of the mask blank that measures up to required accuracy in the nanometer order, can suppress deformation of the mask blank due to formation of the electroconductive film, and can realize a flat shape with high accuracy. Still another object of the invention is to provide a mask, a process for producing the mask and a process for using the mask that use the mask blank.

According to an aspect of the invention, there is provided with a mask blank including at least one of an amorphous and a crystalline material as a mother material. The mother material has transparency and electroconductivity.

According to another aspect of the invention, the mother material is transparent as bulk material characteristics. The mask blank comprises an electroconductive layer having electroconductivity. The electroconductive layer is at least partially formed on a back surface of a front surface part of a plane constituting all directions of the mask blank.

According to another aspect of the invention, a mask blank including: at least one of an amorphous and crystalline material as a mother material. The mask blank comprises an electroconductive layer having transparency and electroconductivity. The electroconductive layer is at least partially formed on a back surface and a front surface part of the mask blank.

According to another aspect of the invention, there is provided with a mask blank including: at least one of an amorphous and crystalline material as a mother material. The mask blank comprises an electroconductive layer having transparency and electroconductivity. The electroconductive layer is at least partially formed on a back surface of a mask and a surface layer region at least partially including a side surface, of a plane constituting all directions of the mask blank.

According to another aspect of the invention, the electroconductive layer is formed with a metallic ion doped and diffused.

According to another aspect of the invention, the metallic ions comprise at least one metallic element of Sn, In, P, As, B, Zn, Ti, Cu, Pb and Ag.

According to another aspect of the invention, the electroconductive layer has a metallic ion distribution in a depth direction of about 1 μm from a surface of the electroconductive layer.

According to another aspect of the invention, there is provided with a mask blank including: at least one of an amorphous and a crystalline material as a mother material. The mask blank comprises a transparent electroconductive film. The transparent electroconductive film is at least partially formed on a back surface of the mask blank.

According to another aspect of the invention, there is provided with a mask blank including: at least one of an amorphous and a crystalline material as a mother material. The mask blank comprises a transparent electroconductive film. The transparent electroconductive film is at least partially formed on a back surface of the mask blank and a region at least partially including a side surface of the mask blank.

According to another aspect of the invention, the transparent electroconductive film is either one of a tin oxide film, an indium oxide film, an ITO film, a zinc oxide film and an indium zinc oxide film.

According to another aspect of the invention, the transparent electroconductive film comprises a noble metal thin film. The noble metal thin film has a thickness in a range of from 5 to 100 nm.

According to another aspect of the invention, the mask blank has a transmittance of 50% or more to light in a thickness direction of a substrate in a spectrum of wavelength in an electromagnetic wave including an excimer laser wavelength and a visible range.

According to another aspect of the invention, at least one of a light shielding film shielding exposure light forming a circuit pattern in a prescribed range and an absorbent film absorbing the exposure light in a prescribed range is formed on a front surface side of the mask blank.

According to another aspect of the invention, the electroconductive layer is formed so as to include a side surface of the mask blank. At least one of the light shielding film and the absorbent film is connected to an electroconductive layer of the side surface of the mask blank.

According to another aspect of the invention, the electroconductive film is formed so as to include a side surface of the mask blank. At least one of the light shielding film and the absorbent film is connected to an electroconductive film of the side surface of the mask blank.

According to another aspect of the invention, the electroconductive layer is formed so as to include both surface and a side surface of the mask blank. At least one of the light shielding film and the absorbent film is formed on an electroconductive layer of the side surface of the mask blank.

According to another aspect of the invention, the electroconductive film is formed so as to include both surface and a side surface of the mask blank. At least one of the light shielding film and the absorbent film is formed on an electroconductive film of the side surface of the mask blank.

According to another aspect of the invention, at least one of the light shielding film and the absorbent film at least partially shields or absorbs a laser light having a spectrum of laser light including an electromagnetic wave to a soft X-ray region, formed by a fluorine dimer laser.

According to another aspect of the invention, a multilayer film having Mo and Si being alternately laminated is at least partially formed on an underlayer side of at least one of the light shielding film and the absorbent film.

According to another aspect of the invention, there is provided with a method for producing a mask blank including: preparing the mask blank having at least one of an amorphous and a crystalline material as a mother material having transparency and electroconductivity; irradiating an mask blank with inspection light in one direction on a front surface or a back surface of the mask blank at a substantially perpendicular or oblique angle or a wide angle range to inspect the mask blank by at least one of diffracted light, reflected light and interference light, when the mask blank not having the light shielding film and the absorbent film formed on the mask blank, is inspected in shape, processing accuracy, flatness or thickness during production by an optical device.

According to another aspect of the invention, there is provided with a method for producing the mask blank according to the above-aspects of the invention, including: preparing the mask blank having at least one of an amorphous and a crystalline material as a mother material having transparency and electroconductivity; and irradiating the mask blank with inspection light in one direction on a surface of the mask blank to inspect the mask blank in shape by at least one of diffracted light, reflected light and interference light, when the mask blank, which has a light shielding film or an absorbent film formed thereon, is inspected in shape, processing accuracy, flatness or thickness during production by an optical device.

According to another aspect of the invention, there is provided with a mask including: a mask for reducing reflection projection exposure using a soft X-ray, wherein the mask has a circuit original plate pattern formed by using the mask blank according to the above-aspects of the invention.

As having been described, according to the above-aspects of the invention, a mask blank has a transparent electroconductive film applied thereto or an electroconductive film formed thereon, whereby such a mask blank, a process for producing the same, a process for using the same, a mask using the same, and a process for producing the mask, and a process for using the mask, that enable application of an electrostatic chuck having a sufficient retaining force, enable simultaneous inspection of the front and back surfaces of the mask blank with ultimate measuring accuracy, suffers extremely low generation of dusts, and can prevent discharge and adhesion of particles.

### BRIEF DESCRIPTION OF THE DRAWINGS

FIG. 1A is a cross sectional view showing a structure of a mask blank of a first embodiment, and FIGS. 1B and 1C are plane views showing structures of the mask blank on the front and back surfaces thereof, respectively.

FIG. 2A is a cross sectional view showing a structure of a mask blank of a second embodiment, and FIG. 2B is a plane view showing a structure of the mask blank.

FIG. 3A is a cross sectional view showing a structure of a mask blank of a third embodiment, and FIG. 3B is a plane view showing a structure of the mask blank.

FIG. 4A is a cross sectional view showing a structure of a mask blank of a fourth embodiment, and FIGS. 4B and 4C are plane views showing structures of the mask blank on the front and back surfaces thereof, respectively.

FIG. 5A is a cross sectional view showing a structure of a mask blank of a fifth embodiment, FIG. 5B is a plane view showing a structure of the mask blank, and FIG. 5C is a plane view showing another structure thereof.

FIG. 6A is a cross sectional view showing a structure of a mask blank of a sixth embodiment, and FIG. 6B is a plane view showing a structure of the mask blank.

FIG. 7A is a cross sectional view showing a structure of a mask blank of a seventh embodiment, and FIGS. 7B and 7C are plane views showing structures of the mask blank on the front and back surfaces thereof, respectively.

FIG. 8A is a cross sectional view showing a structure of a mask blank of an eighth embodiment, and FIG. 8B is a plane view showing a structure of the mask blank.

FIG. 9 is a scheme showing a first process for producing a mask blank according to the above-embodiments.

FIG. 10 is a scheme showing a second process for producing a mask blank according to the above-embodiments.

FIG. 11 is a scheme showing a third process for producing a mask blank according to the above-embodiments.

FIG. 12 is an illustrative view showing a first configuration for inspecting a mask blank according to the above-embodiments.

FIG. 13 is an illustrative view showing another example of the first configuration for inspecting a mask blank according to the above-embodiments.

FIG. 14 is an illustrative view showing a second configuration for inspecting a mask blank according to the above-embodiments.

FIG. 15 is an illustrative view showing another example of the second configuration for inspecting a mask blank according to the above-embodiments.

FIG. 16 is an illustrative view showing a third configuration for inspecting a mask blank according to the above-embodiments.

FIG. 17 is an illustrative view showing another example of the third configuration for inspecting a mask blank according to the above-embodiments.

FIG. 18 is an illustrative view showing a configuration for inspecting a mask blank in a related art.

FIG. 19 is a cross sectional view showing a mask blank according to the above-embodiments.

FIG. 20 is a cross sectional view showing a mask in a production process of a mask according to the embodiments.

FIG. 21 is a cross sectional view showing a completed mask according to the embodiments upon conveying.

### DESCRIPTION OF THE PREFERRED EMBODIMENTS

The embodiments will be described in detail with reference to the attached drawings.

### First Embodiment

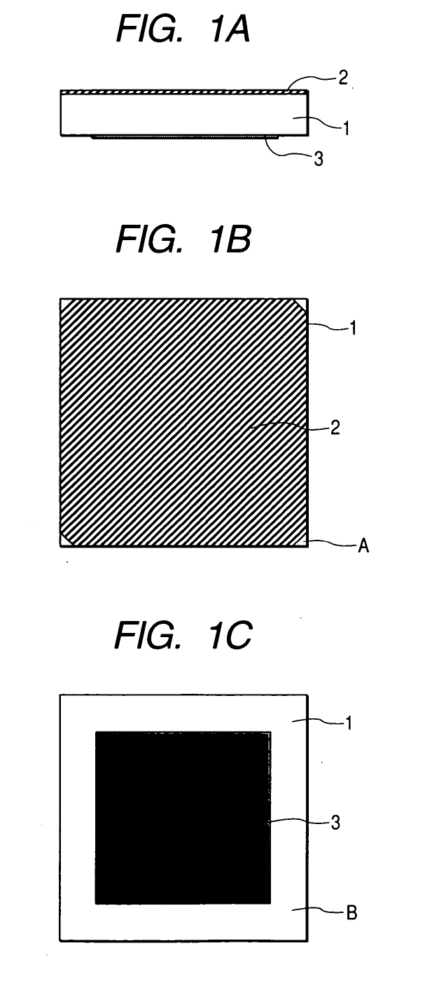

A mask blank according to a first embodiment of the invention will be described with reference to schematic constitutional figures. FIG. 1A is a cross sectional view of the mask blank, and FIGS. 1B and 1C are constitutional views thereof on the front surface and the back surface, respectively. The mask blank has the so-called 6025 outer shape specification, and a mother material 1 is fused silica glass. A light shielding film 2 formed of a Cr film having a thickness of 700 Å and a CrOₓ film having a thickness of 300 Å is provided on the surface. Areas A on the four corners, on which no film is formed, are used for retaining the substrate upon forming films, which are generally used as notch sections for identifying the glass substrate. For example, in SEMI P1-92 (in which the general essential matters of glass substrates for photomasks are disclosed), a substrate of silica glass has two notches facing each other on the diagonal line. An ITO film having a thickness of about 1,000 Å is formed as a transparent electroconductive film on the back surface of the mask blank. The area where the transparent electroconductive film 3 is formed has a size of about 140 mm square. An area B having no film formed on the periphery is used as a contact part on handling the mask or mask blank, on which no film is formed. The shape of the corner part and the chamfer are in accordance with the standard and are not shown in the figures. The ITO film in this example is doped with Sn in a concentration of 5% by weight, and formed by a DC magnetron sputtering method. The electric resistance (specific resistance) thereof is about 4×10⁻⁴ Ω·cm, and the sheet resistance is 40Ω per square. Accordingly, the film has an extremely small resistance in the film thickness direction of 4×10⁻⁹Ω and thus has sufficient electroconductive characteristics.

It has been known that in general, the physical characteristics of an ITO film, particularly the specific resistance and the optical characteristics thereof, greatly depend on the film forming method and the conditions thereon. In this example, the visible light transmittance is 93%. The surface roughness of the film is 2.0 nm (RMS), which shows that a sufficiently smooth surface is formed. The measurement of the surface roughness is carried out by using AFM, and five sites (each having 10 μm square) within the area having the ITO film formed thereon are measured. The aforementioned value is an average value of the values measured at the five sites.

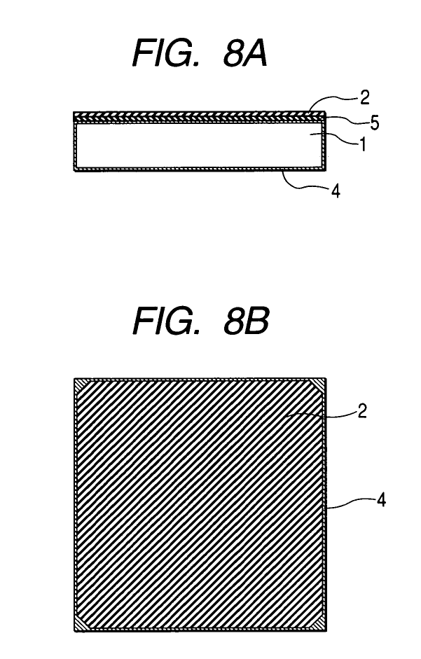

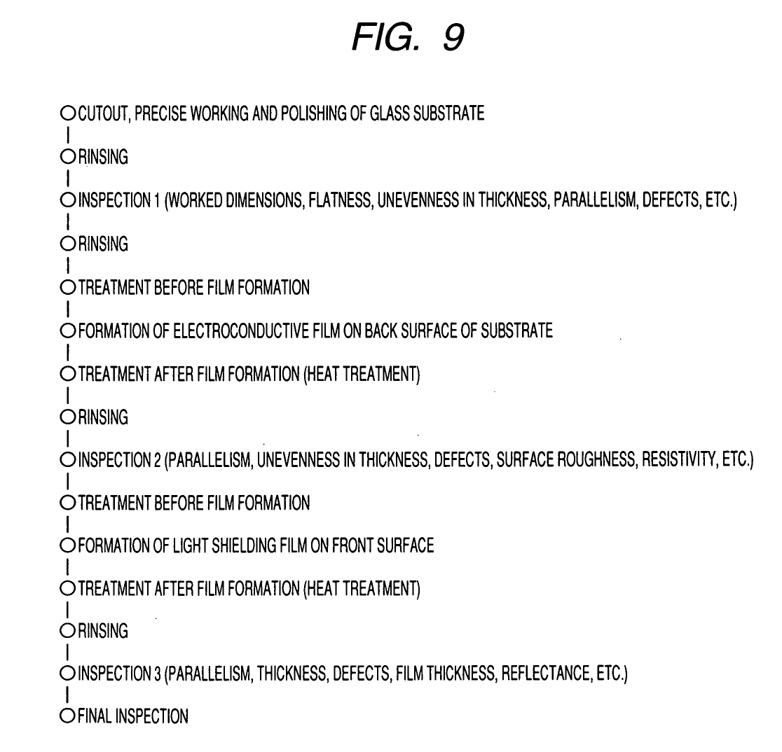

FIG. 9 is a scheme showing the process for producing the mask blank.

Additionally, in order to form a smooth surface, the substrate is subjected to mechanochemical polishing to obtain a surface roughness of 0.9 nm RMS. The polishing step is carried out in the scheme shown in FIG. 9 after completing the heat treatment and the rinsing after forming the film on the back surface.

### Second Embodiment

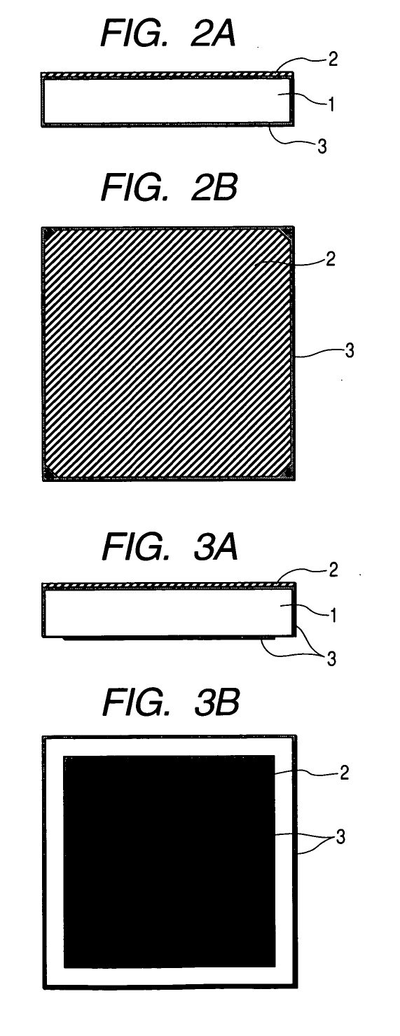

As another embodiment, FIGS. 2A and 2B show a schematic cross sectional view and a schematic front surface view of a mask blank of a second embodiment. In this embodiment, a transparent electroconductive film 3 is formed on the planes constituting all directions of the mask blank, and a light shielding film 2 is provided on the surface, on which a pattern is formed. The transparent electroconductive film is formed on the whole back surface.

### Third Embodiment

As still another embodiment, FIGS. 3A and 3B show a schematic cross sectional view and a schematic front surface view of a mask blank of a third embodiment. In this embodiment, a transparent electroconductive film 3 is formed on the whole front surface, the whole side surface and a part of the back surface.

### Fourth Embodiment

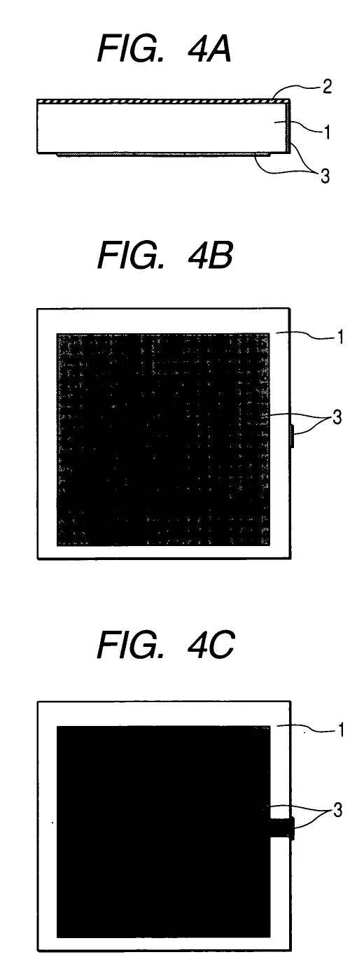

As a further embodiment, FIGS. 4A and 4B show a schematic cross sectional view and a schematic front surface view of a mask blank of a fourth embodiment. In this embodiment, a transparent electroconductive film 3 is formed on a part of the side surface and a part of the back surface. The transparent electroconductive film 3 formed on a part of the side surface is connected to a light shielding film 2 formed on the front surface. Furthermore, as shown in FIG. 4C, the transparent electroconductive films 3 formed on the side surface and the back surface may be connected to each other, and in this case, the electroconductive film for an electrostatic chuck and the electroconductive part on the side surface constitute the same ground potential.

### Fifth Embodiment

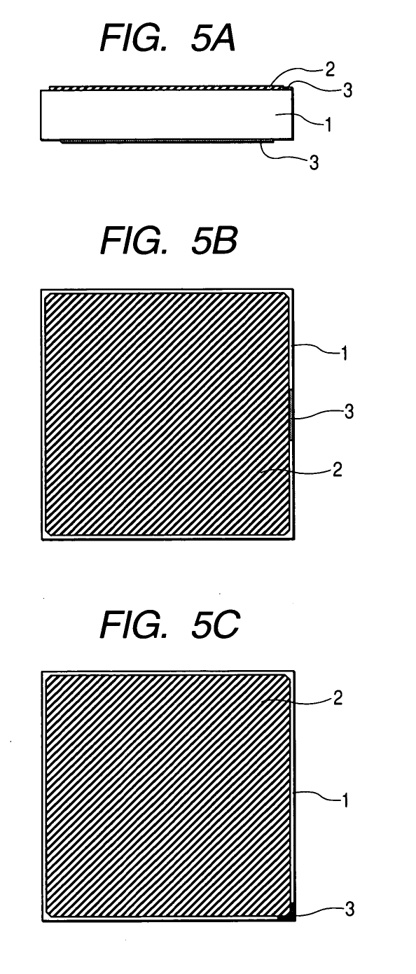

As a further embodiment, FIGS. 5A and 5B show a schematic cross sectional view and a schematic front surface view of a mask blank of a fifth embodiment. In this embodiment, a periphery of a light shielding film 2 is subjected to edge cut in about 1 mm. A transparent electroconductive film 3 is formed on a part of the side surface and a part of the back surface, and the transparent electroconductive film 3 is connected to a part of the light shielding film 2 on the front surface. Another case different in connected part therebetween is shown in FIG. 5c. It is preferred that the location where the transparent electroconductive film 3 connected to the light shielding film is positioned at the optimum location depending on the earthing point of the various kinds of apparatus used. Since the periphery of the light shielding film 2 is subjected to edge cut in about 1 mm, the silica glass as an insulating material used as the mother material 1 of the mask blank is exposed in the edge part. The mask blank having the constitution has such an advantage that even in the case where the edge part is in contact with other members upon handling or retaining in the process steps, dropout of the light shielding film and generation of dusts do not basically occur. The exposed amount of the silica glass as an insulating material is as small as 1 mm, and therefore, there arises only a minor adverse affect due to charging upon drawing with an electron beam.

The mask blanks shown in FIGS. 1A to 5C, the transparent electroconductive film has a structure having the transparent electroconductive film formed on the back surface. The structure is applied to a mask blank for a mask used for reflection projection exposure. This is because in the case where a mask blank is applied to a mask for projection exposure, such problems should be considered that the transmittance of exposure light is decreased in a precise sense due to the transparent electroconductive film on the back surface, and prescribed exposure characteristics cannot be obtained due to change in refractive index.

### Sixth Embodiment

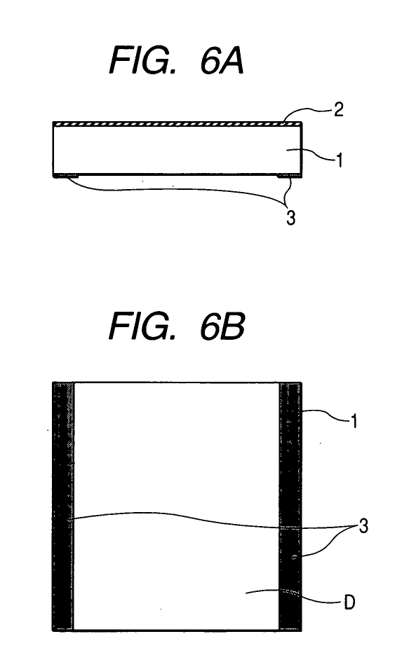

As a further embodiment, FIGS. 6A and 6B show a schematic cross sectional view and a schematic front surface view of a mask blank of a sixth embodiment. In this embodiment, a transparent electroconductive film 3 formed of an ITO film is formed on a part of the back surface. The transparent electroconductive film 3 is formed at a part corresponding to a shape for retaining a completed mask having patterns formed thereon in an exposing apparatus. Accordingly, on a mask stage of the exposing apparatus, the part of the back surface of the mask having the transparent electroconductive film 3 is retained. Since a part D where no film is formed transmits exposure light, no attenuation or phase change of the exposure light occurs in the part, and thus prescribed exposure characteristics can be obtained. The mask blank having the structure of this embodiment is preferred for producing a mask used for the ordinary projection exposure system.

While an ITO film is used as the transparent electroconductive film in the aforementioned embodiments, it is not limited thereto, and the doped amount of tin oxide is not limited to 5% by weight. An ITO film containing In by ion implantation may also be used. The content is preferably about from 5 to 10% by weigh since favorable electroconductivity is obtained. In embodiments, ITO films having a specific resistance that are ordinarily obtained have sufficient characteristics as the electroconductive film. An ITO film having Ag fine particles added may also be used, and the film may be formed at a high temperature and then subjected to quenching. Furthermore, an antimony-doped tin oxide film obtained by doping Sb in an SnO₂ film, a fluorine-doped tin oxide film obtained by doping F in an SnO₂ film, electroconductive films of Cd—Sn—O series, Ga—Zn—O series and In—Zn—O series, and complex oxide accumulated films of In₂O₃—SnO₂ series may also be used. An accumulated thin film of In₂O₃/ITO/SnO₂ may also be used. A noble metal thin film and a low resistance. TiN thin film may also be used as the transparent electroconductive film. In this case, the noble metal thin film and the low resistance TiN thin film are not particularly limited in film forming process and composition as far as they have transparency and electroconductivity.

The film forming process of the electroconductive film is not particularly limited as far as the required film characteristics can be obtained, and examples of the process include a vacuum deposition method, a magnetron sputtering method, a normal pressure CVD method, a plasma CVD method and an MOCVD method. Furthermore, the ordinary methods, such as a sol-gel method, an ion plating method, a coating method and a spray coating method, may also be used. It is necessary that the methods can ensure adhesion property and durability, which relates to dropout of the film and generation of dusts. The formation of the transparent electroconductive film may be carried out by applying the known techniques, such as those disclosed, for example, in “Techniques of Transparent Electroconductive Films”, edited by the 166th Committee of Transparent Oxides and Optical and Electronic Materials, Japan Society for the Promotion of Science, published by Ohmsha, Ltd.

The structures of the mask blanks shown in FIGS. 1A to 6B were subjected to a test for dropout of the transparent electroconductive film on the back surface. The test was carried out for investigating as to whether or not dropout of the film and generation of dusts occurred upon detaching to an electrostatic chuck. The mask blank was repeatedly detached, and the generation amount of particles having a size of 0.3 μm or more was evaluated. The generation amount was measured with a number of detaching of 100. In the structure shown in FIGS. 2A and 2B, particles in the larger amount, i.e., 5 particles, were formed, but it was decided as a permissible level since the amount of particles per one cycle of detaching was less than 0.1. In the structures shown in FIGS. 1A to 1C, 3A and 3B, 4A to 4C, and SA to 5C, the amount of particles was from 3 to 5, and in the structure shown in FIGS. 6A and 6B, the amount of particles was 2. There was such a tendency that the generation amount of particles was increased in proportion to the increase of the contact area to the electrostatic chuck, which was equivalent to the result of the amount of dusts generated upon one cycle of drawing with a drawing apparatus, and thus it was confirmed that no problem was involved. An ordinary ITO film is deteriorated in film durability with increase in frequency of use. However, it is considered that the frequency of particle generation is decreased because the ITO film in the embodiments is improved in surface roughness by polishing in the additional process step.

### Seventh Embodiment

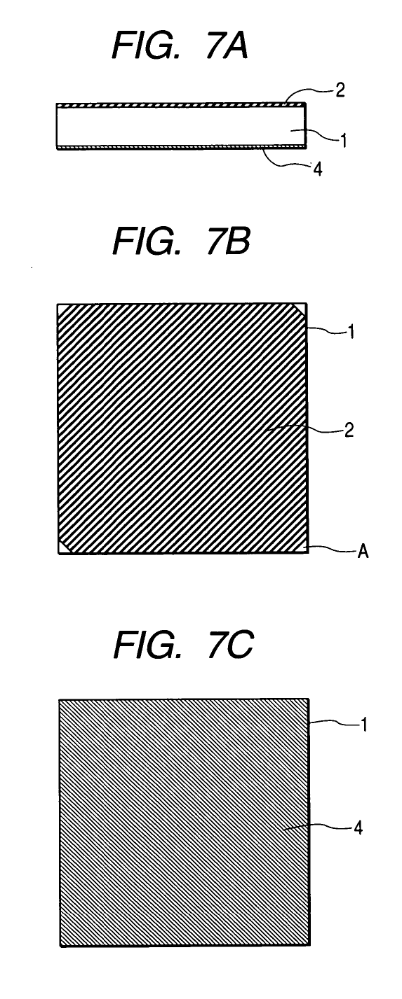

As a still further embodiment, FIGS. 7A to 7C show a schematic cross sectional view, a schematic front surface view and a schematic back surface view of a mask blank of a seventh embodiment. In this embodiment, metallic ions are implanted to silica glass as a mother material of a mask blank, i.e., carriers are introduced to the surface layer of the glass, whereby electroconductivity is imparted thereto. The electroconductive layer had an electric resistance of about 20 Ω·cm.

It has been known that ion implantation brings about increase in surface roughness at low acceleration energy since the action thereof on the glass surface varies depending on the acceleration energy. In general, ions can be implanted in the interior without change of the surface when the energy is several tens keV or more. The distribution of the ions in the depth direction becomes a Gaussian distribution, and the peak position of the distribution (range) depends on the sample and the species of the ions, and the range can be controlled by the acceleration energy of the ions. The relationship between the implantation depth and the energy is roughly determined as about 100 nm in depth with 100 keV in energy. The dose amount of the ions is preferably 10¹⁶ ions/cm² or more, but irradiation damage may occur with a too large dose amount. Examples of the damage include coloration and change in refractive index of the glass mother material.

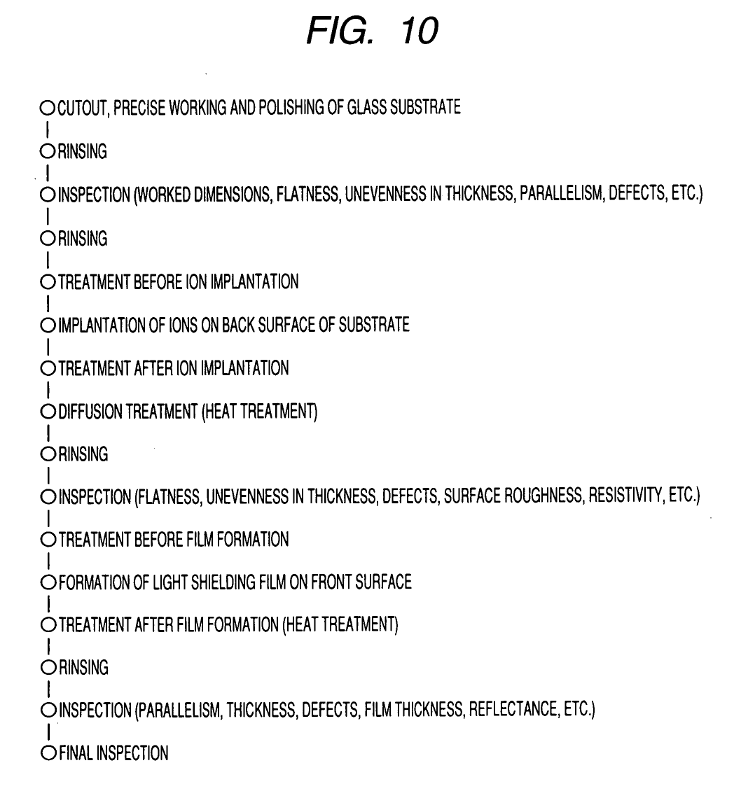

In the embodiment, according to the process shown in FIG. 10, Ti ions were implanted in the ion implantation step at an acceleration energy of 50 keV and a dose amount of 5×10¹⁶ ions/cm². Subsequently, a heat treatment was carried out to diffuse the ions implanted in the glass to the prescribed depth of the substrate, whereby the electroconductive layer was formed. As a result, electroconductivity was imparted by ion implantation without serious deterioration in transparency. The change in refractive index of glass due to ion implantation was about 2%. The visible light transmittance of the silica glass was decreased by about 10%. In order to reduce coloration occurring upon irradiation with a high dose, it is effective that the ion implantation and the heat treatment are carried out different conditions, and for example, there is such a phenomenon that the coloration is reduced to obtain transparency by carrying out a heat treatment at about 400° C. for about 1 hour.

As shown in FIG. 11, furthermore, it was tried that a heat treatment was carried out after completing the first ion implantation step, followed by carrying out the second ion implantation step, so as to reduce irradiation damage of the surface layer. In this case, in order to reduce the roughness of the surface layer of the glass by the first ion implantation step, N ions were implanted in the second ion implantation step. It is possible to carry out not only an ion implantation step for simply imparting electroconductivity, but also an ion implantation step of plural kinds of ions and a heat treatment for such purposes as improvement in surface roughness depending on the process.

In the process shown in FIG. 9, ion implantation may be carried out between the post-treatment (heat treatment) after forming the electroconductive film and the rinsing. In the production process where ion implantation to the electroconductive film is carried out after forming the electroconductive film, the electroconductivity thus imparted can be adjusted, and the transparency can be controlled. The heat treatment may be carried out by changing the atmosphere to nitrogen, oxygen or hydrogen, and for example, the heat treatment carried out in a hydrogen atmosphere modifies the surface layer through reducing action, which generally brings about improvement in electroconductivity.

In addition to the carrier formation by implantation of metallic ions, it is possible that protons are coordinated in the glass by implanting H ions to improve the electroconductivity. In addition to the doping, it is possible that carriers are formed with donor type crystalline defects formed upon ion implantation to impart electroconductivity. The distribution of the crystalline defects generally has a smaller range than the distribution of the implanted ions. The distribution of the implanted ions in the thickness direction of the electroconductive part may be multiplexed by changing the acceleration voltage, and control of the angle of ion implantation is also important. For example, in the case where dense electroconductivity is necessarily imparted over a wide range in the depth direction, multiplexed ion implantation may be a useful measure.

### Eighth Embodiment

As a still further embodiment, FIGS. 8A and 8B show a schematic cross sectional view and a schematic front surface view of a mask blank of an eighth embodiment. In this embodiment, carriers are introduced to the surface layers constituting all directions of the glass, whereby electroconductivity is imparted thereto. The mask blank has a constitution that is used for a reflection mask for EUV exposure, in which ULE (registered trade name) as glass having an ultralow thermal expansion coefficient is used as a mother material 1 of the mask blank, and a Ta alloy having absorbing power to EUV light is used as a light shielding film 2. A multilayer film 5 formed by accumulating Mo and Si exhibiting a high reflectance to EUV light is formed. A buffer film used as an etching stopper and a capping film for preventing surface oxidation, which are not shown in the figures, are formed as intermediate layers between the light shielding film and the multilayer film. Sb ions are implanted at an acceleration voltage of 60 keV and a dose amount of 5×10¹⁷ ions/cm². The electroconductive layer has an electric resistance of about 20 Ω·cm.

The ion implantation area 4 is the whole back surface in the seventh embodiment or the surface layers constituting all directions in the eighth embodiment, and it is possible that the ion implantation is carried out partially to a shape corresponding to the film forming area of the transparent electroconductive film in the first to sixth embodiments, depending on the purpose of the mask blank. In this case, electroconductivity is imparted to a part of the surface layer of the mother material 1. The restriction of the ion implantation area may be effected by using an ordinary shadowing method using an aperture or a method using a resist film as a mask for implantation. It is also possible to restrict the implantation area by controlling the scanning area of the ion beam. The control and in-plane uniformity of the dose amount may not be so strict as in the formation of source and drain in production of semiconductor devices.

It is sufficient that the electroconductivity of the electroconductive layer and the transparent electroconductive film formed on the surface layer may be a value equivalent to those of a p-type or n-type Si wafer, which is generally used as semiconductor silicon, and the electroconductivity is suitably from 1 to 100 cm. It may be also in orders of from 1 μΩ·cm to 1 mΩ·cm as in Cr used in a photomask blank. The values of electroconductivity may be used as a standard on application to an electrostatic chuck. A sheet resistance may also be used as a standard for the electroconductive part. For example, as a standard of the ion implantation amount and the sheet resistance, an ion implantation amount of 1×10¹⁴ ions/cm² provides about 1 kΩ per square, and even in the case where the electroconductive part has a relatively high resistance, there is no problem in earthing as a result of evaluation, whereby charge prevention and application of an electrostatic chuck can be sufficiently effected.

The main stream of principles of adsorption of electrostatic chucks includes the coulomb force and the Johnsen-Rahbeck force (J-R force), and is classified mainly by the resistivity of the chuck material. An electrostatic chuck using ceramics having a low resistance mainly uses the J-R force, and for retaining a substrate having an electroconductivity equivalent to an Si wafer, an adsorption power of several kgf/cm² is realized with an application voltage of several hundreds V. A chuck formed of an insulating material, such as glass, uses the coulomb force, by which a voltage of several kV is required to obtain an adsorption power, and furthermore, a sufficient adsorption power cannot be obtained upon adsorbing glass. However, the embodiments has such an advantage that by using a mask blank having an electroconductive part applied thereto as in the embodiments, a sufficient adsorption power can be obtained with an ordinary electrostatic chuck.

### Ninth Embodiment

As a still further embodiment, an example is shown in that introduction of carriers to the surface layers constituting all directions of glass is effected by introducing a metallic element by a thermal diffusion method. The thermal diffusion method utilizes such a phenomenon that a metallic element migrates from an area having a high concentration to an area having a low concentration through thermal diffusion until reaching the thermal equilibrium state of the metal. In this embodiment, the gas phase diffusion method and the solid phase diffusion method will be described. In the gas phase diffusion method, the same measures as in doping of impurities to a Si wafer is applied. All the reactions are carried out by using a diffusion furnace, in which a reaction gas is generated and doped in a mask blank. Firstly, a metallic element to be doped is vaporized to a suitable vapor pressure to form a metal gas. In this embodiment, boron (B) is used as the metallic element, and an inert gas (Cl₂) is used as the carrier gas, to which O₂ is added to effect reaction. The metal gas is reacted with quartz as a mother material of the mask blank at a prescribed temperature to effect thermal diffusion of the metallic element into the interior of the mother material of the mask blank. According to the reactions 4BCl₃+3O₂→2B₂O₃+6Cl₂ and B₂O₃+SiO₂→B₂O₃·SiO₂, a glassy product B₂O₃·SiO₂ is formed on the mother material of the mask blank, from which B is supplied.

In the case where the solid diffusion method is used, for example, a substrate for diffusion target containing a metallic element to be doped is prepared and is placed in a diffusion furnace to face a mother material of a glass mask. The assembly is heated to a prescribed temperature, whereby a vaporized gas of the metallic element is generated from the substrate for diffusion target, and the metallic element is doped by reaction with the mother material of the mask blank. As the substrate for diffusion target, a boron nitride plate can be generally used. The use of a boron nitride plate realizes uniform doping, and is suitable for imparting electroconductivity to the surfaces constituting all directions of the mother material of the mask blank. As another example of the solid phase diffusion method, for example, a polysilicon layer having ions implanted therein is separately formed on the mother material of the mask blank, and may be used as a diffusion source. In the case of using the method, the polysilicon layer is removed after completing the diffusion process to impart electroconductivity to the mother material of the mask blank, which brings about complexity in process steps. In the method, however, ions can be distributed to a surface layer of a small depth to facilitate reduction in resistance, and furthermore, only the uppermost surface layer is modified, whereby such an advantage that the influence of ion implantation, such as change in refractive index, coloration and increase in surface roughness of the mother material, can be suppressed to a minimum level. For example, after forming polysilicon having a thickness of 100 nm on a mother material of a mask blank by a CVD method, arsenic is implanted thereto at an acceleration voltage of 50 keV and a dose amount of 1×10¹⁶ ions/cm², and then the mother material is subjected to a heat treatment at 800° C. for 30 minutes as an activation treatment to diffuse arsenic. In this case, the measurement with SIMS (secondary ion mass spectroscopy) reveals that the depth of arsenic in the mother material of the mask blank is about 90 nm, and a high doping density in the order of 102⁰ cm⁻³ is obtained. It is also possible similarly that a metallic ion doped in an SOG (spin-on-glass) film is diffused to impart electroconductivity to a mother material of a mask blank. In this case, it is advantageous that SOG is transparent. Moreover, the application of electroconductivity in the embodiments can be carried out by other techniques, such as a focused ion beam and a laser beam.

### Tenth Embodiment

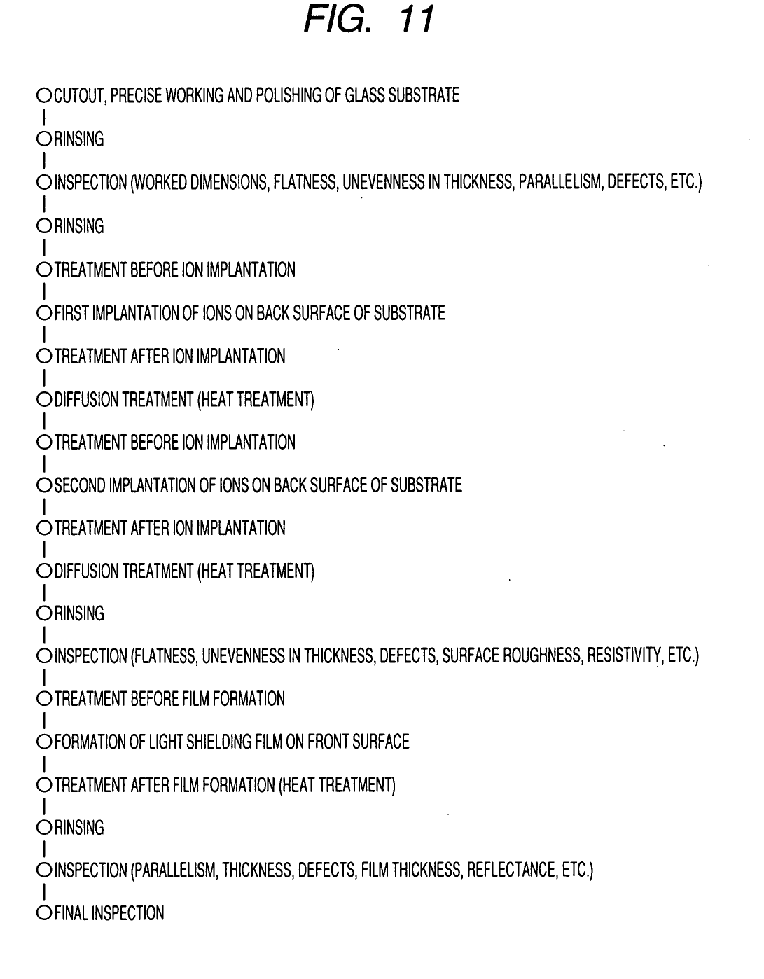

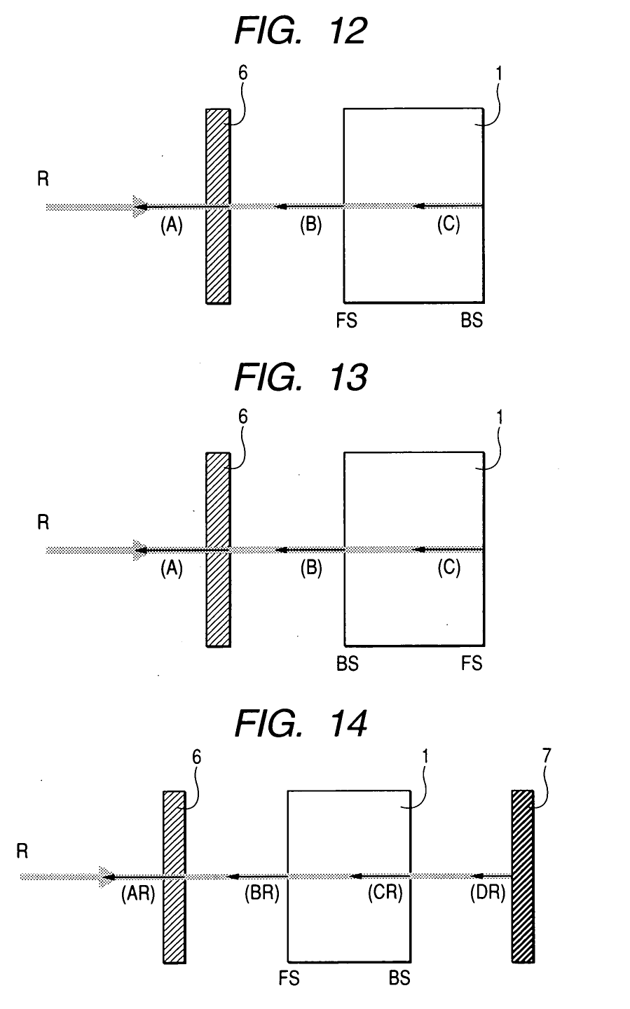

An inspection of the surface shape (including flatness, unevenness in thickness, and parallelism) of the mask blanks having been produced in the aforementioned manners will be described with reference to FIGS. 12 to 15. This embodiment is for demonstrating that an inspection with high accuracy can be carried out because the electroconductive film or electroconductive layer has transparency. In inspection 1, a shape of a glass mother material is inspected with reference to the production process of a mask blank in the ninth embodiment, and in inspection 2, a shape of a mask blank after forming an electroconductive film on the back surface is inspected.

In the process of the inspection 1, the surface shape (working accuracy, including flatness, unevenness in thickness, and parallelism) of a mask blank before forming a film is measured. In the process of the inspection 2, the surface shape after forming the film on the back surface is measured. The mother material is necessarily suffers microscopic or macroscopic deformation through a certain process, and therefore, a mother material having sufficient working accuracy in the inspection 1 is even necessarily subjected to another inspection process after completing such a process as film formation and ion implantation. In particular, a mask blank for a mask for exposure is required to have high optical accuracy, and it is necessary that the flatness, parallelism and surface roughness thereof are strictly controlled. Furthermore, the mother material of the mask blank is necessarily a highly pure transparent body to exposure light as in the case of silica glass, and therefore, it is also necessary that internal defects and non-uniformity in refractive index are strictly controlled.

In the inspection process, for example, a measuring apparatus utilizing a so-called flatness interferometer as shown in FIG. 12 is often used. In a flatness interferometer, a substrate to be measured (a mother material 1 of a mask blank formed of silica glass in this embodiment) is disposed to face a reference mirror 6 of a half mirror having an optical surface with sufficiently high accuracy, with a prescribed distance. The substrate as a target material is irradiated with laser light R as measuring light, and reflected light and interference light from the planes are measured to inspect the flatness of the target material. The optical flatness accuracy of the reference mirror 6 is generally from 1/20 to 1/50 of the wavelength of the measuring light while it depends on the measurement resolution. A He—Ne laser (wavelength: 632.8 nm) is generally used as the measuring light. In the figure, the laser light R is radiated from the left side onto the mother material 1 through the reference mirror 6. The mother material 1 is disposed in such a manner that the front surface (FS) used for pattern formation is on the left side. The shape of the front surface of the mother material 1 with the reference mirror 6 as the reference level is measured from an interference fringe formed by the reflected light (A) from the reference mirror 6 and the reflected light (B) from the front surface (FS) of the mother material 1. Similarly, the unevenness in optical thickness of the mother material 1 is measured from an interference fringe formed by the reflected light (B) from the back surface (BS) of the mother material and the reflected light (C) from the front surface (FS) thereof. The reflected light (A) and the reflected light (C) are adjusted to provide a certain physical distance to avoid interference therebetween. Because an interference fringe practically observed contains multiple interference patterns and interference fringes between various planes, so-called fringe scan by wavelength modulation is carried out to separate the interference fringes accurately, whereby the surface shapes of the surfaces are measured. The shapes can be measured with high accuracy since the initial phases of the measuring points are obtained by the fringe scan. Multiple interference fringes (moire image) formed by multiple reflection of the reflected light (B) on the right side plane of the reference mirror 6 are separated by the fringe scan to avoid adverse affects on measuring accuracy.

The shape of the front surface of the mother material 1 can be obtained by subtracting the unevenness in physical thickness from the back surface shape. Since the unevenness in optical thickness is a sum of the unevenness in physical thickness, the unevenness in glass medium (refractive index) and the errors of the optical system of the measuring apparatus, the shape of the front surface of the mother material 1 thus calculated is a mere approximate value in a strict meaning. However, it is ensured in manufacturing that the mother material has uniform distribution of refractive index inside, and the optical thickness can be assumed as the physical thickness by measuring the value of refractive index by another means. In this case, the front surface shape and the back surface shape can be found simultaneously. In the case where the refractive index distribution is not uniform, on the other hand, the back surface shape of the mother material 1 is measured by counterchanging the positional relationship of the front and back surfaces of the mother material (the mother material 1 reset by counterchanging the left and right sides thereof in the figure).

However, in the case where the measurement target (mother material 1) is reset, measurement errors associated with deformation of the measurement target occurring on resetting the target material (including deformation due to the weight of the mask itself), the measurement noise (including influence of vibration and fluctuation in temperature), and optical errors and detection errors of the measuring apparatus influence twice, and thus there is such a risk that the measurement accuracy becomes insufficient. For example, assuming that the measurement error (uncertainty) of a single measurement is 20 nm (3σ), and all the error factors occur randomly, the error is increased in 42 times by resetting the measurement target. Therefore, it depends on the measurement accuracy in the process of the inspection 1 as to whether the measurement target is measured by a single measurement to avoid errors due to resetting of the measurement target, or the measurement target is reset.

In the case where the required measurement accuracy is high, it is preferred that the shapes of the front and back surfaces (flatness) and the unevenness in physical thickness of the mother material 1 are measured simultaneously by utilizing two reference mirrors 6 and 7 as shown in FIG. 14. In this method, resetting of the measurement target can be avoided. Furthermore, the shapes of the surfaces are measured simultaneously, the same random error factors are applied to the measurement results of the respective surfaces, which brings about such an advantage that measurement accuracy close to the ideal state can be obtained. In FIG. 14, the reference mirror 6 is a half mirror, and the reference mirror 7 is an ordinary optical flat mirror. The optical flatness accuracy of the mirrors is generally from 1/20 to 1/50 of the wavelength of the measuring light, and the mirrors have been sufficiently calibrated. In the case where the measurement target has a high reflectance, the measurement cannot carried out essentially, but in the case where the reflectance is about 50%, measurement with sufficient accuracy can be carried out by utilizing, in combination, adjustment in detection sensitivity and separation of interference fringes by fringe scan.

As described below, according to a configuration shown in FIG. 14, a front surface shape of the mother material 1 is measured from an interference fringe formed by a reflected light (AR) of the reference mirror and an interference fringe between reflected light (BR) of front surface (FS) of the mother material. A back surface shape of the mother material 1 is measured by an interference fringe formed by a reflected light (CR) of the back surface (BS) of the mother material and a reflected light of the reference mirror 7.

When strength of signal representing a reflected light (AR) and signal representing a reflected light (BR) is 1, respectively, the reflected light (CR) and the reflected light (DR) are 0.25, respectively. Both strength of signals (AR) and (BR) is attenuated in proportion to square of optical transmittance of a mother material to be measured. The interference fringe between the reflected light (AR) and the reflected light (BR) (referred to as “a first interference fringe” in this paragraph) is generated without any problem, since both strength is substantially same. An interference fringe between the reflected light (CR) and the reflected light (DR) (herein, referred to as “a second interference fringe”) is formed as well. Signal strength of the second interference fringe is about 6% of signal strength of the first interference fringe. According to the embodiment, a sensitivity of a detector is adjusted in order to detect the first and second fringes, and an image processing is performed by a fringe scan so that the interference fringe is separated.

When two different interference fringes are detected at the same time, the sensitiveness of the detector is within a predetermined range, and is not saturated. When a ratio of the two different interference fringes is about 10:1, even though the sensitiveness of the detector is enhanced, a small signal of an interference fringe can be detected without saturation with a high degree of accuracy. When a reflection of a subject to be measured is over 50%, front surface shape and back surface shape can be detected at the same time. Accordingly, when the reflection of the subject to be calculated is equal to or more than 50%, the front surface shape and the back surface shape can be detected at the same time with the configuration shown in FIG. 14.

According to the configuration shown in FIG. 14, the front surface shape of the mother material 1 is measured from an interference fringe formed by the reflected light (AR) from the reference mirror 6 and the reflected light (BR) from the front surface (FS) of the mother material 1. The back surface shape of the mother material 1 is measured from an interference fringe formed by the reflected light (CR) from the back surface (BS) of the mother material 1 and the reflected light (DR) from the reference mirror 7.

The unevenness in physical thickness of the mother material 1 is calculated from the front surface shape and the back surface shape thus measured. The unevenness in physical thickness measured herein is mere unevenness that is a difference in flatness between the front surface shape and the back surface shape, which is calculated as unevenness, but the absolute thickness is not measured.

However, what is problematic in shape inspection of a mask blank is the unevenness in physical thickness but not the absolute thickness, and thus no problem occurs in the production process of this embodiment. This is because in the case where there arises a problem of image shift, in which the image location of a pattern is deviated within the plane due to irregularity on the mask surface, as described in the chapter of related art, the unevenness in physical thickness of the mask blank (or the mask) contribute to the flatness, and thus the unevenness in physical thickness should be measured. Since the absolute thickness can be compensated by leveling on retaining the mask blank (or the mask), it causes no particular problem and may be measured in the order of micrometer at most.

As having been described, in the configuration shown in FIG. 14, measuring light is incident in one direction on the front surface to obtain such an advantage that the shapes of the front and back surfaces and the unevenness in physical thickness of the measurement target can be measured simultaneously without approximation. Furthermore, the measurement target may not be reset, i.e., the measurement target may not be counterchanged for measuring the back surface after measuring the front surface, whereby the deterioration in measuring accuracy and uncertainty on measurement caused by resetting the measurement target can be reduced. Therefore, the measurement can be carried out with sufficiently high accuracy to improve the production yield.

The process of the inspection 2 after forming the electroconductive film on the back surface of the substrate in the production process shown in FIG. 9 will be described. What is important for realizing inspection with high accuracy is the fact that the electroconductive film is transparent. As having been described, it is important that as in the configuration shown in FIG. 14, for example, measuring light is incident in one direction on the front surface of the mask blank to measure the shapes of the front and back surfaces and the unevenness in physical thickness of the measurement target simultaneously, and the condition for realizing such a feature is that the measurement target is transparent to the measuring light.

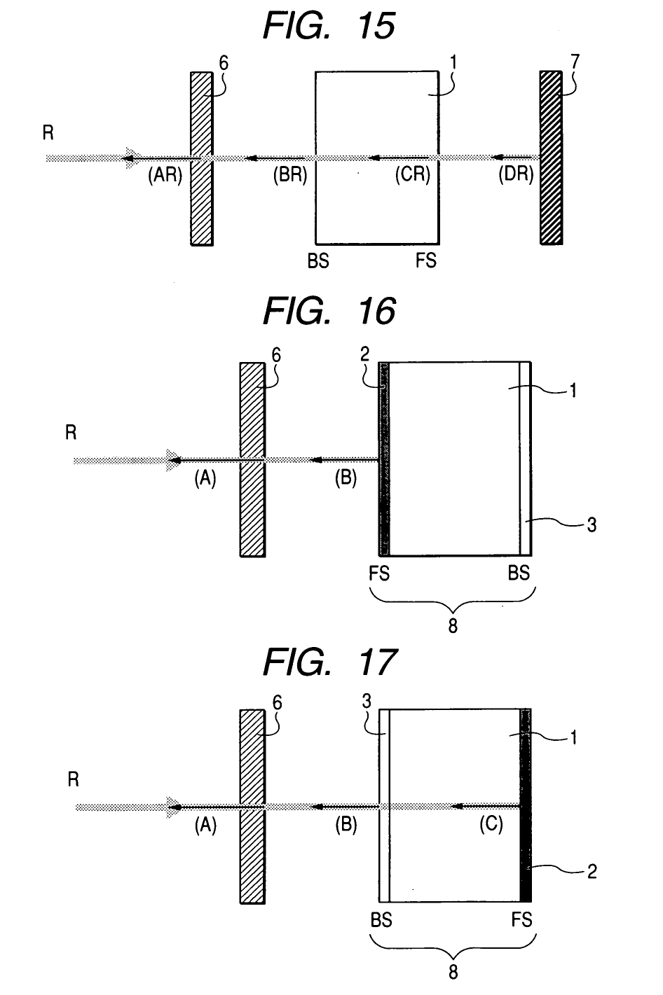

The inspection with high accuracy can be realized by using the method shown in FIG. 14 owing to the fact that the electroconductive film on the back surface of the substrate is transparent, whereby the yield can be improved. Silica glass used as the mother material of the mask blank has a high transmittance of 99% or more to visible light, and the transparent electroconductive film has a transmittance of about 80% in the worst case, which is a level that does not cause any problem on inspection accuracy. The configuration shown in FIG. 15 is the same as that in FIG. 14 except that the front and back surfaces of the mother material 1 are counterchanged, and these configurations are equivalent to each other in terms of simultaneous measurement of the front and back surface and the unevenness in physical thickness of the measurement target.

In the case where the mother material of the mask blank is imparted with electroconductivity by doping metallic ions as in FIGS. 10 and 11, deterioration in transparency by implantation of ions is only several percents at most, which causes no problem in transmittance to the measuring light on measurement, and thus the measurement can be sufficiently carried out by the methods described in FIGS. 14 and 15. The change in refractive index by implantation of ions is typically about 5%, which affects the measurement accuracy only slightly. This is because the shapes of surfaces are measured by irradiating with the same measuring light, and thus all the measurements of the surfaces are affected thereby to the same extent. In the case where ions are implanted to the surfaces constituting all directions of the mother material of the mask blank, inspection with sufficient accuracy can be carried out by the aforementioned measurement.

In the case where such glass materials as ULE (registered trade name) or Zerodur (registered trade name) having a lower expansion coefficient than silica glass are used as the mother material of the mask blank, inspection with sufficient accuracy can be similarly carried out. In the case of ULE (registered trade name) glass, for example, the mask blank having anisotropy in transmittance is produced to have light transmittance in the thickness direction thereof, whereby the inspection method can be applied thereto. While Zerodur (registered trade name) is colored in light yellow, the reduction in transmittance thereby is about 30%, and thus the inspection method can be applied thereto.

### Eleventh Embodiment

The inspection of the surface shape of the mask blank will be described for the case where an opaque film, such as a metallic film, is formed. The inspection effected after forming a light shielding film on the front surface side will be described herein.

In FIG. 9, the front and back surfaces and the unevenness in thickness of the mask blank are measured in the inspection 3. The inspection is carried out for measuring microscopic or macroscopic deformation of the mask blank after forming the light shielding film, and is secondly important after the final inspection.

In the process of the inspection 3, the light shielding film as an opaque film is formed on the front surface side of the mother material 1 of the mask blank, and therefore, when the configuration in FIG. 12 (or FIG. 14) is applied, the configuration shown in FIG. 16 is obtained, by which only the shape of the front surface (FS) of the mask blank 8 is measured.

Thus, there arises such a problem that the shape of the back surface of the final mask blank cannot be inspected. The shape of the back surface can be inspected by resetting the mask blank, but there is a risk of deterioration in measuring accuracy due to resetting. Accordingly, a method shown in FIG. 13 (or FIG. 15) where measuring light is incident on the back surface side of the mask blank is favorably employed. In this case, the configuration shown in FIG. 17 is employed, in which the shape of the back surface of the mask blank 8 is measured from an interference fringe formed by the reflected light (A) from the reference mirror 6 and the reflected light (B) from the transparent electroconductive film 3 on the back surface (BS).

Similarly, the unevenness in optical thickness of the mother material 1 and the transparent electroconductive film 3 is measured from an interference fringe formed by the reflected light (B) from the transparent electroconductive film 3 on the back surface (BS) of the mask blank 8 and the reflected light (C) from the interface between the mother material 1 and the light shielding film 2. The shape of the front surface of the mother material 1 can be obtained by adding the unevenness in physical thickness, which is obtained from the unevenness in optical thickness with consideration of the refractive index, to the shape of the back surface of the mask blank 8, while it is an approximation method. Since the unevenness in optical thickness thus measured is a sum of the unevenness in physical thickness, the unevenness in glass medium (refractive index) and the errors of the optical system of the measuring apparatus, the shape of the front surface of the mother material 1 thus calculated is a mere approximate value in a strict meaning.

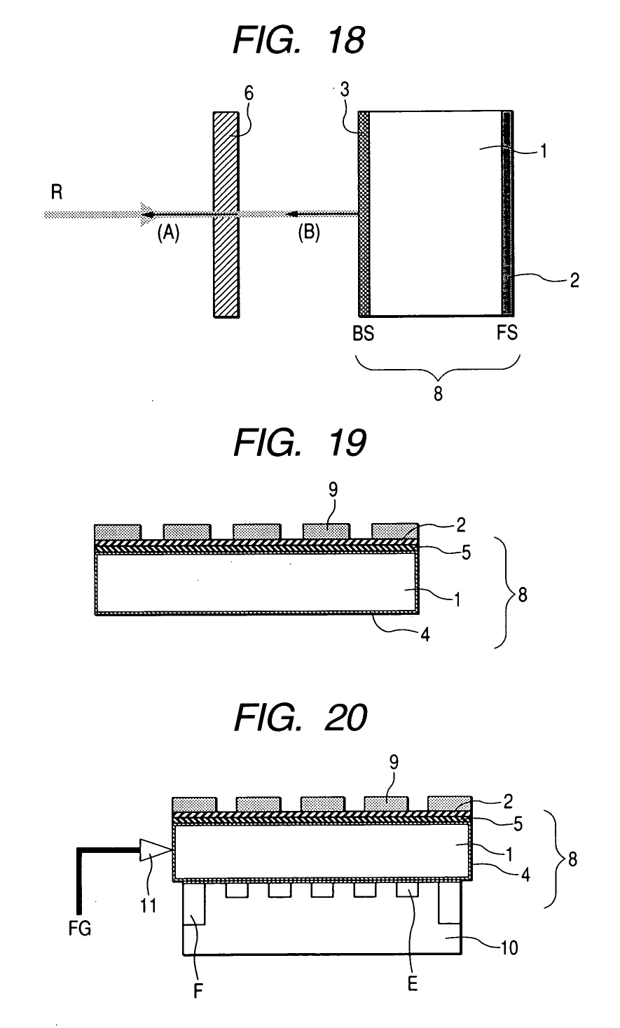

However, it is a significant advantage that the measurement can be simultaneously carried out as described above, as compared to the case where the electroconductive film on the back surface is an opaque film, in which the measuring method herein cannot be carried out because of the configuration shown in FIG. 18. The unevenness in optical thickness measured herein is a value obtained from an interference fringe of the interface between the light shielding film 2 and the mother material 1 and therefore is not the shape of the front surface of the mask blank 8 in a strict meaning.

However, the thickness of the light shielding film is generally measured separately or monitored in situ upon forming the film, and is controlled at least in the order of nanometer (in the order of angstrom generally). Therefore, taking the thickness value into consideration, the shape of the front surface of the final mask blank 8 can be inspected. As having been described, since the electroconductive film (or the electroconductive layer) on the back surface is transparent, even in the final inspection process after forming a light shielding film on the front surface side in the production process of the mask blank, the shape of the back surface of the mask blank can be measured, and while it is an approximation method, the shape of the front surface having the light shielding film formed thereon can be measured and inspected.

### Twelfth Embodiment

A method for retaining a mask blank to a production apparatus upon producing a mask by using the mask blank will be described with reference to FIGS. 19 to 21. The retaining method during the process for forming a pattern by etching, and the retaining method upon conveying the completed mask to an exposure apparatus will be described.

FIG. 19 shows a mask blank 8 having a resist pattern 9 produced by the ordinary mask production process, i.e., by using a mask blank having the constitution shown in FIG. 8, a resist is coated with a resist coater, and after a heat treatment, a pattern is drawn with an electron beam drawing apparatus, followed by developing, to obtain the resist pattern 9. The mask blank is subjected to dry etching with the resist as an etching mask in a magnetron RIE etching apparatus. FIG. 20 shows the state where the mask blank 8 is retained with a stage 10 having an electrostatic chuck in the etching apparatus. The stage 10 is connected to a cable for the electrostatic chuck from a high voltage power supply (which are not shown in the figure).

The symbol E denotes grooves provided in the stage 10 for preventing dusts from being bitten upon contacting the stage 10 with the mask blank, and F denotes a groove provided for preventing the stage 10 from interfering with a tip of a conveying robot arm for conveying and setting the mask blank on the stage 10. The mask blank 8 is grounded (FG) from the side wall thereof through an earthing terminal 11. According to the constitution, the mask blank 8 is retained with an electrostatic chuck on the state, and the charge on the surface of the mask blank fed by the etching ion gas is released through the earthing terminal 11 by ground (FG).

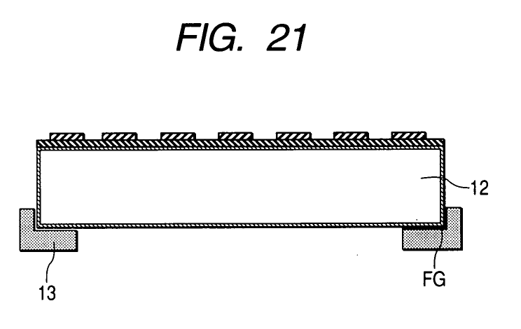

The case where a mask 12 completed in the exposure apparatus is conveyed with a conveying robot will be described. In this embodiment, two arms are used as tip arms of the conveying robot for supporting a part of the back surface of the mask. As shown in FIG. 21, the tip arms 13 of the conveying robot are grounded (FG), and the mask 12 is conveyed in such a state that the tip arms are in contact with the electroconductive part of the mask 12. In this case, the mask 12 is in a grounded state and is not charged upon conveying, as far as it is always in contact with the conveying arms. Accordingly, the electrostatic dust collecting function due to charging does not exhibited to prevent dusts from being attached to the mask upon conveying.

As having been described, in the embodiments, a mask blank is applied with a transparent electroconductive film or formed with an electroconductive layer by doping metallic ions, whereby an electrostatic chuck having a sufficient retaining force can be applied thereto, and electroconductivity is applied to a glass mask blank or mask as an insulating material to prevent charging, and such a phenomenon can be prevented that particles are attached thereto due to the electrostatic dust collecting function.

Particularly, in the case where the electroconductive film or the electroconductive layer is formed by ion doping, electroconductivity is imparted by implanting ions to the mother material of the glass mask blank itself to alter the physical characteristics of the surface layer of the glass in a depth where the ions are implanted, whereby the effects that cannot be attained by the conventional techniques can be obtained. In general, upon handling a completed mask in an exposure apparatus, a problem occurs by generation of dusts due to physical contact between the mask and the handling mechanism, which is so serious as equivalent to the problem of the dust collecting function due to charging. The generation of dusts ascribed to such a phenomenon that the films formed on the mask blank, such as the light shielding film and the anti-reflection film, are scratched on contact during handling, and the risk of generation of dusts is increased when the film is insufficient in adhesion strength, or the film itself is brittle. In some cases, dropout of the film itself causes a problem. The transparent electroconductive film is in the same situation in terms of generation of dusts from the film, and there is a risk that the transparent electroconductive film becomes a source of dusts depending on the forming location and the forming method thereof. However, in the case where ions are implanted to glass itself to make the surface layer thereof as an electroconductive layer, the glass mother material is hard to generate dusts in comparison to the case of applying the transparent electroconductive film, and there is essentially no problem of dropout of the film, whereby the risk of dust generation due to contact can be avoided.

While it has been demanded that an EUVL mask is retained with an electrostatic chuck, the embodiments provide such a mask that can be applied with an electrostatic chuck and can realize prevention of dust generation and prevention of charging. Particularly, in EUV lithography, irradiation with EUV light forms photoelectrons emitted from a light shielding film and a multilayer film on the surface of the mask by the photoelectric effect, and a problem occurs due to the phenomenon that the surface is positively charged. Accordingly, it is important that the mask during EUV exposure is grounded. However, a multilayer film and an absorbent film used in an EUVL mask are brittle, and a problem of dust generation arises even in the case where an ordinary earthing mechanism is made in contact therewith. In particular, dusts generated in the case where a multilayer film and an absorbent film formed on the front surface of the mask (surface for forming patterns) is made in contact with an earthing mechanism are liable to be adhered to the front surface of the mask, and as a result, they bring about pattern defects. Accordingly, it is necessary to prevent the earthing mechanism from being in contact with the films, or in alternative, it is necessary to develop such a contact mode that no dust is generated upon contact. On the other hand, in the embodiments, electroconductivity is imparted to a glass part on the side surface of the mask, on which no multilayer film or absorbent film is provided, and the part is grounded, whereby dusts generated upon contact of the earthing mechanism can be suppressed from being attached to the surface for forming patterns. Similarly, in the embodiments, a part of the periphery of the mask surface, on which no multilayer film or absorbent film is provided, is grounded, whereby even in the case where dusts are formed from the grounded part, the dusts thus generated are suppressed from being attached to the surface for forming patterns. Furthermore, electroconductivity may be applied to the mask blank on a limited area where the earthing mechanism is in contact therewith.

It is demanded that an EUVL mask is inspected in flatness on the front and back surfaces thereof in the order of nanometer, and in order to realize the inspection, it is necessary that as described in the embodiments, the front and back surfaces are measured simultaneously to avoid influence due to deformation of the mask upon retaining caused by resetting the mask. In the embodiments, the electroconductive film or the electroconductive layer has transparency to light for measuring the flatness, whereby the simultaneous measurement can be realized.

### Modified Embodiment

The invention is not limited to the aforementioned embodiments. The transparent electroconductive film may be formed by combining plural materials, and may have different film constitutions depending on the locations on the mask blank, on which the film is formed. The measure for imparting electroconductivity is not particularly limited as far as electroconductivity can be imparted to a prescribed area thereby. The area of the mother material of the mask blank where electroconductivity is imparted directly by doping is not limited to those in FIGS. 7A to 8B, and a doping area similar to the areas for forming the transparent electroconductive films in FIGS. 1A to 6B may be employed.

While positive ions are doped in the embodiments, negative ions may also be used. The doping of metallic ions and the formation of the transparent electroconductive film may be used in combination. The materials of the masks such as the light shielding film and the glass mother material, are not limited to those disclosed in the embodiments. While fused silica glass and a glass material having an ultralow thermal expansion coefficient are used in the embodiment, calcium fluoride glass as a crystalline material and composite glass may also be used. In general, electroconductivity can be easily imparted to crystalline glass as compared to an amorphous material.

The production process of the mask blank is not limited to those of the embodiments. Electroconductivity may be imparted in the final step of the production of the mask blank under no influence of the order of the process steps. In particular, with respect to masks having a complex structure or having plural film, such as a mask for halftone and a mask for Levenson-type phase shift, the invention can be applied to mask blanks corresponding to these masks. The masks and mask blanks used herein have a flat form, but a substrate partially having a structure, such as projections and recession, and a supporting frame, may be used. For example, the invention can be applied to a mask having a pellicle. The value of electroconductivity is also not limited to those in the embodiments, and furthermore, there may be unevenness in electroconductivity within a plane.

The term “mask blank” referred herein means a mask before forming patterns, which is ordinarily referred to as a mask substrate, a mask blank, a blank mask and the like. The term “mask” referred herein mainly means a mask having patterns formed therein, which is ordinarily referred to as a reticle, a reticle substrate, a mask substrate and the like.

Upon embodiments of the invention, various modifications may be made therein without departing from the spirit and scope of the invention.

What is claimed is:

1. A mask blank comprising:
at least one of an amorphous and a crystalline material as a mother material, wherein the mother material has transparency and electroconductivity.

2. The mask blank according to claim 1, wherein the mother material is transparent as bulk material characteristics,
wherein the mask blank comprises an electroconductive layer having electroconductivity, and
wherein the electroconductive layer is at least partially formed on a back surface of a front surface part of a plane constituting all directions of the mask blank.

3. A mask blank comprising:
at least one of an amorphous and crystalline material as a mother material,
wherein the mask blank comprises an electroconductive layer having transparency and electroconductivity, and
wherein the electroconductive layer is at least partially formed on a back surface of a front surface part of the mask blank.

4. A mask blank comprising:
at least one of an amorphous and crystalline material as a mother material, wherein the mask blank comprises an electroconductive layer having transparency and electroconductivity,
wherein the electroconductive layer is at least partially formed on a back surface of a mask and a surface layer region at least partially including a side surface, of a plane constituting all directions of the mask blank.

5. The mask blank according to claim 3, wherein the electroconductive layer is formed with a metallic ion doped and diffused.

6. The mask blank according to claim 3, wherein the metallic ions comprise at least one metallic element of Sn, In, P, As, B, Zn, Ti, Cu, Pb and Ag.

7. The mask blank according to claim 5, wherein the electroconductive layer has a metallic ion distribution in a depth direction of about 1 μm from a surface of the electroconductive layer.

8. A mask blank comprising:
at least one of an amorphous and a crystalline material as a mother material, wherein the mask blank comprises a transparent electroconductive film, and
wherein the transparent electroconductive film is at least partially formed on a back surface of the mask blank.

9. A mask blank comprising:
at least one of an amorphous and a crystalline material as a mother material, wherein the mask blank comprises a transparent electroconductive film,
wherein the transparent electroconductive film is at least partially formed on a back surface of the mask blank and a region at least partially including a side surface of the mask blank.

10. The mask blank according to claim 8, wherein the transparent electroconductive film is either one of a tin oxide film, an indium oxide film, an ITO film, a zinc oxide film and an indium zinc oxide film.

11. The mask blank according to claim 8, wherein the transparent electroconductive film comprises a noble metal thin film, and
wherein the noble metal thin film has a thickness in a range of from 5 to 100 nm.

12. The mask blank according to claim 1, wherein the mask blank has a transmittance of 50% or more to light in a thickness direction of a substrate in a spectrum of wavelength in an electromagnetic wave including an excimer laser wavelength and a visible range.

13. The mask blank according to claim 2, wherein at least one of a light shielding film shielding exposure light forming a circuit pattern in a prescribed range and an absorbent film absorbing the exposure light in a prescribed range is formed on a front surface side of the mask blank.

14. The mask blank according to claim 8, wherein at least one of a light shielding film shielding exposure light forming a circuit pattern in a prescribed range and an absorbent film absorbing the exposure light in a prescribed range is formed on a front surface side of the mask blank.

15. The mask blank according to claim 13, wherein the electroconductive layer is formed so as to include a side surface of the mask blank, and
wherein at least one of the light shielding film and the absorbent film is connected to an electroconductive layer of the side surface of the mask blank.

16. The mask blank according to claim 14, wherein the electroconductive film is formed so as to include a side surface of the mask blank, and
wherein at least one of the light shielding film and the absorbent film is connected to an electroconductive film of the side surface of the mask blank.

17. The mask blank claim 13, wherein the electroconductive layer is formed so as to include both surface and a side surface of the mask blank, and
at least one of the light shielding film and the absorbent film is formed on an electroconductive layer of the side surface of the mask blank.

18. The mask blank claim 14, wherein the electroconductive film is formed so as to include both surface and a side surface of the mask blank, and
at least one of the light shielding film and the absorbent film is formed on an electroconductive film of the side surface of the mask blank.

19. The mask blank according to claim 13, wherein at least one of the light shielding film and the absorbent film at least partially shields or absorbs a laser light having a spectrum of laser light including an electromagnetic wave to a soft X-ray region, formed by a fluorine dimer laser.

20. The mask blank according to claim 13, wherein a multilayer film having Mo and Si being alternately laminated is at least partially formed on an underlayer side of at least one of the light shielding film and the absorbent film.

21. A method for producing a mask blank comprising:
preparing the mask blank having at least one of an amorphous and a crystalline material as a mother material having transparency and electroconductivity;
irradiating an mask blank with inspection light in one direction on a front surface or a back surface of the mask blank at a substantially perpendicular or oblique angle or a wide angle range to inspect the mask blank by at least one of diffracted light, reflected light and interference light, when the mask blank not having the light shielding film and the absorbent film formed on the mask blank, is inspected in shape, processing accuracy, flatness or thickness during production by an optical device

22. A method for producing a mask blank according to claim 13, comprising:
preparing the mask blank having at least one of an amorphous and a crystalline material as a mother material having transparency and electroconductivity; and
irradiating the mask blank with inspection light in one direction on a surface of the mask blank to inspect the mask blank in shape by at least one of diffracted light, reflected light and interference light, when the mask blank, which has a light shielding film or an absorbent film formed thereon, is inspected in shape, processing accuracy, flatness or thickness during production by an optical device.

23. A mask comprising:
a mask for reducing reflection projection exposure using a soft X-ray, wherein the mask has a circuit original plate pattern formed by using the mask blank according to claim 1.
